(19) United States
(12) Patent Application Publication
(10) Pub. No.: US 2018/0148029 A1
(43) Pub. Date: May 31, 2018

(54) Device for Varying a Pedal Resistance, Brake System

(71) Applicant: Robert Bosch GmbH, Stuttgart (DE)

(72) Inventors: Thomas Friedrich, Ingersheim (DE); Simon Trautmann, Stuttgart (DE)

(21) Appl. No.: 15/577,309

(22) PCT Filed: Apr. 19, 2016
(86) PCT No.: PCT/EP2016/058618

§ 371 Date: Nov. 27, 2017

(30) Foreign Application Priority Data
May 27, 2015 (DE) 10 2015 209 732.3

(51) Int. Cl. B60T 13/575; B60T 13/72; B60T 7/04; B60T 13/569

(52) U.S. Cl. CPC B60T 13/575; B60T 13/72; H01L 41/09; B60T 13/569; B60T 7/04

(57) ABSTRACT

A device for varying a pedal resistance of a hydraulic brake system includes at least one electroactive polymer actuator. The device further includes a reaction disc. The reaction disc has at least two polymer actuators. The at least two polymer actuators are independently controllable. Additionally, the at least two polymer actuators are arranged coaxially relative to one another.

The invention relates to a device for varying a pedal resistance of a hydraulic brake system, having at least a first electroactive polymer actuator.

The invention further relates to a brake system for a vehicle, in particular motor vehicle, having a main brake cylinder, having a brake pedal to displace a piston in the main brake cylinder, having a brake booster and having a device for varying a pedal resistance of the brake pedal.

The invention further relates to a method for operating the device or the brake system.

### PRIOR ART

In hydraulic brake systems of motor vehicles, a brake pedal is usually actuated by the driver, wherein the brake pedal displaces a piston in a main brake cylinder often with the support of a brake booster, wherein a hydraulic assembly such as, for example, an ESP or ABS assembly is connected to the outputs of the main brake cylinder. As a result, brake fluid is introduced into the hydraulic assembly and conducted to the wheel brake cylinders. There, the introduced volume increases the brake pressure and leads to a braking action as a result of pressing of the brake linings onto the brake disks. Different configurations of brake boosters, for example, pneumatic, hydraulic or also electromechanical brake boosters, are known.

It is furthermore already known from the Offenlegungsschrift (first publication of the application documents) DE 11 2007 000 961 D5 that a pedal resistance can be varied by a polymer actuator.

### DISCLOSURE OF THE INVENTION

The device according to the invention with the features of claim 1, the brake system according to the invention with the features of claim 8 and the method according to the invention with the features of claim 11 have the advantage that integration of the polymer actuator into the brake system is carried out or can be carried out in a particularly simple and space-saving manner and that the brake pedal resistance can be advantageously adjusted as a function of different operating states. The device according to the invention is characterized in that it has a reaction disk which has at least two polymer actuators which can be actuated independently of one another and which are arranged coaxially to one another. The polymer actuator has therefore become, together with a further polymer actuator, a component of a reaction disk. Hydraulic brake systems generally have a reaction disk which is connected between the pedal and the piston to be displaced. Reaction disks are normally composed of a plastic, in particular, elastomer and are deformable by the action of pedal force and/or brake booster force. The material of conventional reaction disks cannot be compressed in this case and is used both in vacuum brake boosters and in electromechanical brake boosters. It is vital for the pedal feeling, in particular the pedal resistance. Due to the fact that in the present case the reaction disk comprises two polymer actuators, the properties of the reaction disk can be easily changed during operation so that the pedal feeling, in particular the pedal resistance, is correspondingly varied. Since the reaction disk is in any case usually present, a replacement with the device according to the invention is easily possible and leads to the above-mentioned advantages. Due to the fact that the polymer actuators are arranged coaxially to one another, they act in a uniform manner between the brake pedal and the piston as seen over their circumference. Of course, piston and brake pedal do not necessarily directly bear against the reaction disk, rather it is preferably provided that the brake pedal acts through a brake pedal rod on the reaction disk and that the reaction disk acts on the piston of the main brake cylinder through a piston rod or passes on the force introduced by brake pedal and/or brake booster. The reaction disk is preferably restricted in its outer circumference so that, irrespective of an energization/actuation of the polymer actuators, the reaction disk can only have a maximum definable outer diameter or outer circumference. This means that an expansion of the reaction disk in the radial direction is only possible up to a predefined extent. This has the result that, if one of the polymer actuators is energized, it contracts and as a result pushes elastomer material radially outwards or inwards, the other polymer actuator, if it is not actuated/energized, is also not pushed outwards or inwards, rather is radially compressed and as a result axially extended. This restriction of the outer circumference can be ensured, for example, by a solid shell wall or sleeve in which the polymer actuators are arranged.

According to one preferred further development of the invention, it is provided that the polymer actuators are formed separately from one another. The polymer actuators can thus be produced and mounted separately from one another which can lead to low-cost production. The separate polymer actuators are preferably arranged and fastened on a joint carrying element, wherein the carrying element serves in particular as a bearing element for the brake pedal or the pedal stand of the brake pedal and/or for the piston or the piston rod.

According to a preferred further development of the invention, it is provided that the polymer actuators have at least one joint dielectric elastomer layer. The polymer actuators are thus not formed separately, but rather have joint functional elements, in particular a joint elastomer layer. A particularly compact formation of the reaction disk is made available as a result. The interaction of the inner polymer actuator with the outer polymer actuator or vice versa is furthermore improved as a result of the joint elastomer layer. If, for example, the inner polymer actuator is actuated so that it is compressed in the axial direction, it expands radially. As a result, a force acts directly on the outer polymer actuator through the joint elastomer surface. Movements of the outer polymer actuator also correspondingly act on the inner polymer actuator. It is provided in particular that the polymer actuators have several joint elastomer layers. It is particularly preferably provided that all the elastomer layers are assigned both to the inner and the outer polymer actuator. Reference is made to the fact that the outer polymer actuator preferably has annular, in particular circular ring-shaped electrodes. It can, however, alternatively also be provided that the outer polymer actuator has several ring segment-shaped, in particular circular ring segment-shaped electrodes which are arranged around the inner polymer actuator.

According to one preferred further development of the invention, it is provided that at least one electrode of the polymer actuators, in particular of each polymer actuator, protrudes at least in sections laterally with respect to the electrical contact. The at least one electrode thus protrudes so that it can be easily electrically contacted. It is in particular provided that adjacent electrodes project in different directions, wherein it is particularly preferably provided that several electrodes of a polymer actuator project alternately in one and in another direction so that simple contacting of every second electrode is possible.

It is furthermore preferably provided that the polymer actuators are housed jointly, wherein the housing is formed deformably so that actuation of the polymer actuators leads to a corresponding deformation of the housing which has a corresponding effect on the operation of the brake system or the reaction disk. It can, for example, be provided that the housing has elastically deformable end faces.

According to one alternative embodiment of the invention, it is preferably provided that the housing is formed to be overall elastically deformable. As a result, a simple and particularly variable change in the form of the reaction disk and thus a corresponding variation of the brake pedal resistance are ensured. Alternatively, it is preferably provided that at least the shell outer wall of the housing is produced from a solid, in particular elastically non-deformable material in order to restrict the previously described restriction of the outer circumference or outer diameter of the reaction disk.

The housing is particularly preferably produced from the material of the joint elastomer layer. It is particularly provided that the material of the elastomer layer lies not only between the electrodes, rather also encompasses the electrodes both radially and at the end side so that the polymer actuators are entirely enclosed by the material of the elastomer layer. A particularly compact and easy to handle unit is produced as a result of this.

The brake system according to the invention is characterized by the device according to the invention.

As a result of this, the above-mentioned advantages are achieved. Further features and advantages will become apparent from the description above and from the subordinate claims.

It is particularly provided that the reaction disk is connected or arranged between a brake piston which is displaceable by the brake pedal and a booster piston which is displaceable by the brake booster on one hand and the piston of the main brake cylinder on the other hand, wherein the inner polymer actuator of the reaction disk has a diameter which is smaller than or equal to the diameter of the brake piston so that an actuation of the inner polymer actuator initially only has an effect on the actuation of the brake piston by the brake pedal. It is provided that the brake piston and the booster piston are also expediently arranged coaxially to one another, wherein the brake piston is arranged on the inside and the booster piston is arranged on the outside in the manner of a cylinder sleeve. The outer diameter of the booster piston preferably corresponds at least substantially to the outer diameter of the reaction disk so that the booster piston interacts in particular with the region of the reaction disk in which the outer polymer actuator is arranged so that the braking characteristics can be influenced during actuation of the brake booster by an actuation of the outer polymer actuator. According to one preferred further development of the invention, it is provided that the restriction described above of the outer circumference of the reaction disk is formed by the booster piston and/or the piston of the main brake cylinder, wherein the booster piston or the piston of the main brake cylinder has for this purpose in each case an axial receiving recess into which the reaction disk can be placed and which has an inner diameter which corresponds to the maximum permitted outer diameter of the reaction disk.

It is furthermore preferably provided that at least one of the polymer actuators is formed as a stack actuator and/or that at least one of the polymer actuators is formed as a roller actuator. In particular, the two polymer actuators of the reaction disk are formed in each case identically so that both polymer actuators are either stack actuators or roller actuators.

The method according to the invention with the features of claim 11 is characterized in that the polymer actuators of the reaction disk are actuated independently of one another as a function of a desired pedal resistance. It is in particular provided that only the inner polymer actuator, only the outer polymer actuator or both polymer actuators are energized or actuated as a function of the desired pedal resistance. Further features and advantages of the method will become apparent from the description above and from the claims.

The invention should be explained in greater detail below on the basis of the drawing. In the drawing

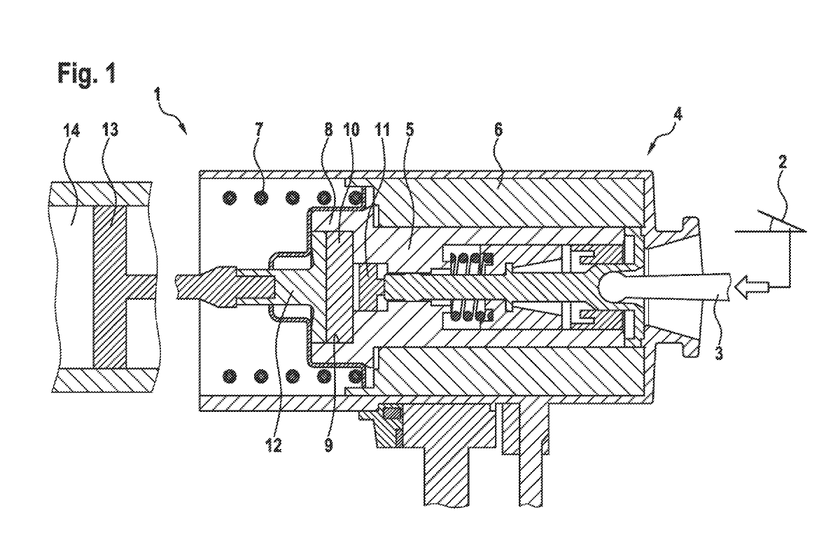

FIG. 1 shows a simplified sectional representation of a brake system,

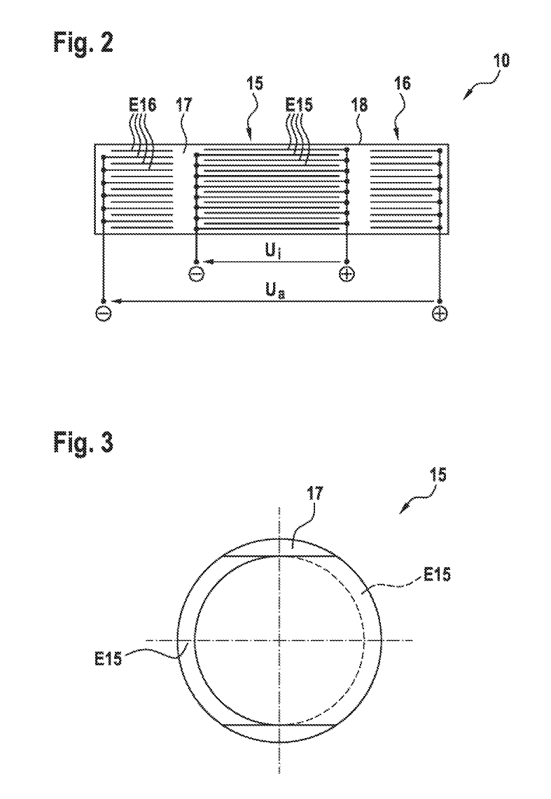

FIG. 2 shows a simplified sectional representation of a reaction disk of the brake system,

FIG. 3 shows a simplified top view of the reaction disk,

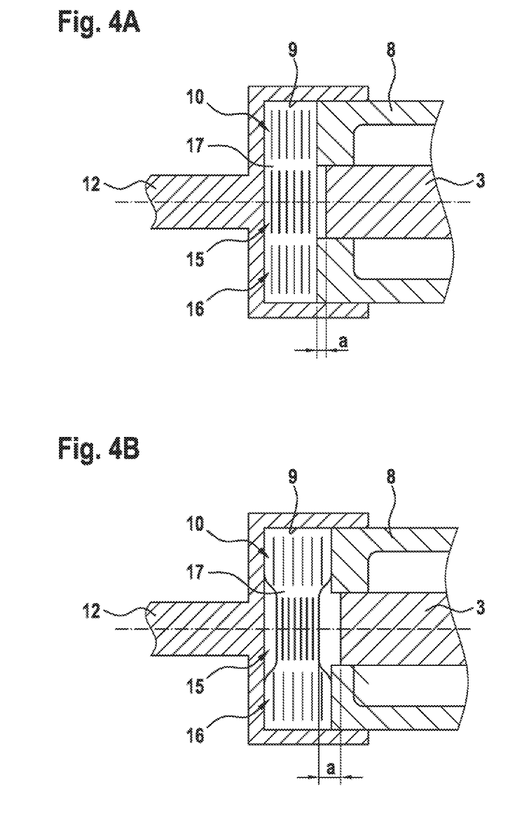

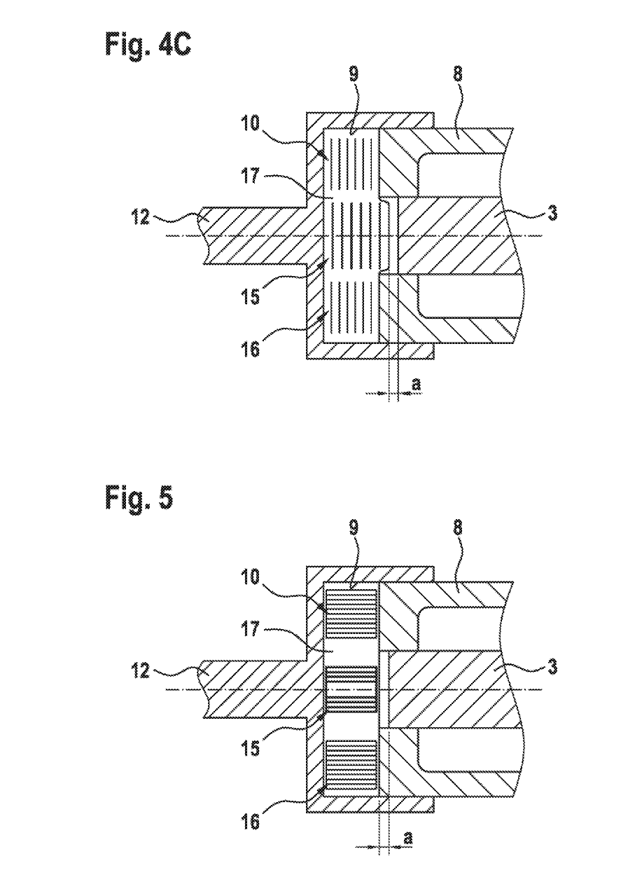

FIGS. 4A to 4C show different operating states of the brake system,

FIG. 5 shows a further exemplary embodiment of the reaction disk and

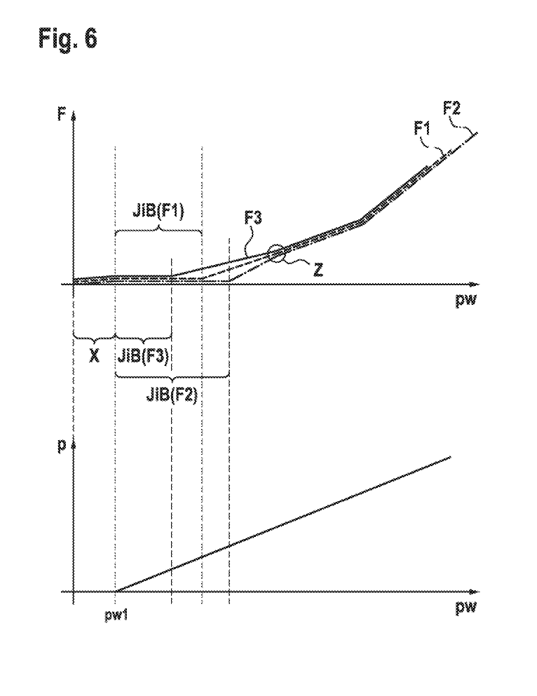

FIG. 6 shows a characteristic curve of the brake system.

FIG. 1 shows, in a simplified sectional representation, a brake system 1 of a motor vehicle, not represented in greater detail here. Brake system 1 has a brake pedal 2 which is only represented schematically here and which is connected mechanically to a brake piston 3 which is mounted longitudinally displaceably in a brake booster. Brake booster 4 has a booster piston 5 arranged coaxially to brake piston 3 and displaceable parallel thereto, which booster piston is displaceable by an actuator 6 counter to the force of a spring element 7. Booster piston 5 has, at its free end 8, an axial receiving recess 9 in which a reaction disk 10 is arranged. Reaction disk 10 is aligned coaxially to booster piston 5. A clearance 11 in which brake piston 3 is guided displaceably also opens into receiving recess 9 so that brake piston 3, when it is actuated by brake pedal 2, is displaced in the direction of reaction disk 10 until it strikes it.

On the side facing away from booster piston 9 and brake piston 3, reaction disk 10 bears against a piston rod of a piston 13 which can be displaced in a main brake cylinder 14 of brake system 1 for generating a hydraulic pressure. Piston 13 can thus be actuated by brake pedal actuation and/or by activation of actuator 6. In the case of a conventional formation of reaction disk 10, this would be produced from an elastomer which generates a pedal resistance during actuation with the brake pedal which is typical for operation of brake system 1 and can be haptically detected by the driver.

In the present case, however, according to FIG. 2 which shows reaction disk 10 in a sectional representation, it is provided that reaction disk 10 has two polymer actuators 15 and 16 which are arranged coaxially to one another and to booster piston 5. Outer polymer actuator 16 is formed to be annular, in particular circular ring-shaped, so that it encloses inner polymer actuator 15 on the circumferential side. The outer diameter of polymer actuator 15 corresponds substantially to the outer diameter of booster piston 5 on the axial bearing face for reaction disk 10. Both polymer actuators 15 and 16 can be actuated or energized independently of one another. Both polymer actuators 15, 16 have in each case several electrodes E15 or E16 between which in each case a dielectric elastomer is arranged. If electrodes E15, E16 of respective polymer actuator 15 or 16 are energized or acted upon with an electric voltage, electrodes E15 or E16 of respective polymer actuator 15, 16 mutually attract one another, as a result of which the elastomer lying between them is compressed. Because the elastomer is formed to be non-compressible, the compression leads to an enlargement of the surface area perpendicular to the direction of compression. In the present case, it is provided that elastomer 17 provided between electrodes E15 and E16 is formed as a joint elastomer of polymer actuators 15 and 16 so that the elastomer layers are pulled through both polymer actuators 15, 16 and in particular also form a housing 18 of polymer actuators 15, 16 and thus of reaction disk 10. Reaction disk 10 thus represents a single monolithic reaction disk 10 with polymer actuators 15, 16 integrated therein. As an alternative to the shown embodiment, it can also be provided that reaction disk 10 is formed from two or more polymer actuators 15, 16 which are formed separately from one another and which are glued together or formed/arranged separately from one another.

FIG. 3 shows on the basis of a simplified top view of polymer actuator 15 how electrodes E15, E16 of both polymer actuators can be electrically contacted. It is provided in the present case for this purpose that electrodes E15 protrude laterally in sections. It is provided in particular that the adjacent electrodes project alternately on different sides of polymer actuator 15 so that every second electrode on one side of the polymer actuator and every further electrode lying therebetween of the same polymer actuator can be electrically contacted on the opposite side. As a result, the individual electrodes can be contacted alternately with negative and positive voltage potential. The electrodes do not necessarily have to protrude on opposite sides, rather they can also protrude adjacent to one another, as seen in the top view.

FIGS. 4A to 4C show advantageous reaction disk 10 in the installed state in brake system 1, in each case in a simplified representation.

According to FIG. 4A, polymer actuators 15 and 16 are not activated/energized or not acted upon with an electric voltage. Reaction disk 10 is located in its neutral state in this case.

If only inner polymer actuator 15 is energized, as shown in FIG. 4B, polymer actuator 15 is compressed. As a result of the constant volume, reaction disk 10 expands in this region which is not under tension. This expansion is only possible in the form of a change in thickness, i.e. in an expansion in the axial direction in the region of outer polymer actuator 16 since reaction disk 10 has an outer diameter which corresponds to the inner diameter of receptacle 9 so that it cannot radially expand in receiving recess 9.

It is clearly apparent in FIG. 4B that travel a between brake piston and reaction disk 10 is enlarged in comparison to the original state according to FIG. 4A. If the driver presses brake pedal 2, travel a, in the case of which brake system 1 builds up almost no counter-force on brake pedal 2 but a braking action is generated by the brake booster, is large if actuator 6 is simultaneously actuated. What is known as the jump-in range is large here, i.e. a greater braking action is achieved without it being possible to sense a corresponding counter-force on the pedal, i.e. a corresponding pedal resistance. The driver would experience what is known as “sharp braking”. Travel 1 together with the jump-in travel of brake system 1 is large, but is not felt in normal operation by the driver as a result of the “sharpness” of brake system 1.

FIG. 4C shows an operating state in which only outer polymer actuator 16 is placed under tension. As a result, outer polymer actuator 16 compresses together axially. Reaction disk 10 must expand in the region, which is not under tension, i.e. in the region of inner polymer actuator 15. It also applies here to elastomer that it can only expand to where there is still space, namely axially in the center, i.e. in the direction of brake piston 3, as shown in FIG. 4C. The outer diameter of inner polymer actuator 15 is selected to be smaller than the outer diameter of piston 3 in clearance 11 so that polymer actuator 15 can only deform in regions into clearance 11, as shown in FIG. 4C.

Travel a between brake piston 3 and reaction disk 10 is significantly reduced as a result. If the driver now presses brake pedal 2, travel a is very quickly overcome and brake system 1 can build up a counter-force on the brake pedal by means of reaction disk 10 while brake booster 4 generates a braking action. Here, the jump-in is smaller, i.e. a corresponding pedal resistance also occurs approximately when the braking action sets in. The driver would define or experience this as “linear braking” which is very easy to meter. Travel a together with the jump-in travel of brake system 1 is small in this case.

Naturally, both inner and outer polymer actuator 15, 16 can be simultaneously supplied with electrical voltage, but the form of reaction disk 10 does not change as a result of this. Without ancillary mechanical conditions, reaction disk 10 would compress approximately uniformly and have an increased diameter. In the installed state, i.e. in receptacle 9 of booster piston 8, this is not possible as a result of the dimensioning of the outer diameter of reaction disk 10 and of the inner diameter of receiving recess 9. Reaction disk 10 also cannot be compressed as a result of this.

As an alternative to the formations of polymer actuators 15, 16 presented in the exemplary embodiment described above as stack actuators, it is also conceivable to form one or both polymer actuators as roller actuators, as shown by way of example in FIG. 5. Active reaction disk 10 is composed in this case, as shown in FIG. 5, from two roller actuators arranged concentrically with respect to one another: outer polymer actuator 16 which acts on booster piston 8 and inner polymer actuator 15 which acts on brake piston 3. The mode of operation with the change in play or travel a is the same as in the example described above. Other arrangements can also be selected such as, for example, an inner roller actuator for brake piston 3 and several roller actuators of the same size, distributed annularly around the inner roller actuator for booster piston 8. It is important here that the actuators can be actuated independently of one another against brake piston 3 and booster piston 8.

While it is shown in FIG. 1 that reaction disk 10 is encompassed radially by booster piston 8, it is also possible according to the exemplary embodiments of FIGS. 4A to 4C and FIG. 5 to enclose reaction disk radially by piston rod 12 so that axial receiving recess 9 is formed in piston 13 or in piston rod 12.

There are several possibilities in terms of the structure of active reaction disk 10: according to a first exemplary embodiment, the reaction disk is composed of one piece, i.e. inner and outer polymer actuator 15, 16 are glued to one another by elastomer material 17. Elastomer material 17, which is then located between and around inner and outer polymer actuator 15, 16, can be the same as the dielectric which is located between individual electrodes E15, E16 or also different. Alternatively, reaction disk 10 can also be represented by two polymer actuators formed separately from one another. These two are joined together in brake system 1 if polymer actuators 15, 16 are correspondingly arranged in receptacle 9.

Reaction disk 10 influences brake system 1 by changing the jump-in range, i.e. how quickly travel a is used up. Before travel a is overcome, free travel must be overcome. After overcoming the free travel, a mechanical coupling of brake system 1 is present, i.e. travel a is used up and a brake force can be transmitted from brake piston 3 or booster piston 8 to piston 12.

FIG. 6 shows brake pressure p and pedal force F plotted in a diagram against pedal path pw. Free travel x as well as the characteristics of pedal force F are furthermore plotted in the case of a conventional reaction disk, shown by a dashed line F1, in comparison to pedal force F2 in the case of a large travel a and pedal force F3 in the case of a small travel a.

Once free travel x has been overcome, different force/travel characteristic curves F1 and F2 are produced depending on the size of the play or travel a which can be influenced or varied as described above by reaction disk 10. Even after the end of jump-in range JiB, the pedal characteristics are influenced by the advantageous formation of reaction disk 10, such as shown, for example, at point Z. The build-up of brake pressure, i.e. the deceleration of the vehicle, is already carried out from the start of jump-in range JiB if booster body 8 pushes on reaction disk 10 in the case of brake travel pw₁ and free travel x was overcome.

It should be noted that, from a certain brake force, the effect of actively deformed reaction disk 10 acts disadvantageously. From a certain brake force, a higher force prevails on reaction disk 10 than that generated by polymer actuators 15, 16. This means that the driver and brake booster 4 can overpressure the preset geometry of reaction disk 10 until it no longer influences the pedal feeling. This point is marked by Z in FIG. 6.

As a result of the advantageous formation, the “brake disk wiping function” can furthermore be supported in that active reaction disk 10 is electrically deformed without actuation of brake pedal 2 in such a manner that outer polymer actuator 16 increases axially or becomes thicker so that a low pressure can be built up between booster piston 8 and piston rod 12, which low pressure is sufficient to place the brake linings of wheel brakes connected to the main brake cylinder against the brake disks in order, for example, to remove a film of water from the brake disks. In the case of lightweight ACC brakes, the braking action can furthermore be easily changed or influenced, for example, by an opposite activation, by targeted activation of reaction disk 10.

1. A device for varying a pedal resistance of a hydraulic brake system, comprising:
at least one electroactive polymer actuator; and
a reaction disk, the reaction disk including at least two polymer actuators
wherein the at least two polymer actuators are configured to be actuated independently of one another and are arranged coaxially to one another.

2. The device as claimed in claim 1, wherein the at least two polymer actuators are formed separately from one another.

3. The device as claimed in claim 1, wherein the at least two polymer actuators have at least one joint dielectric elastomer layer.

4. The device as claimed in claim 1, wherein at least one electrode of the at least two polymer actuators protrudes laterally with respect to an electrical contact.

5. The device as claimed in claim 3, wherein:
the at least two polymer actuators are jointly housed in a housing, and
the housing is deformable at least in regions.

6. The device as claimed in claim 5, wherein the housing is elastically deformable.

7. The device as claimed in claim 5, wherein the housing is manufactured from a same material as the at least one joint dielectric elastomer layer.

8. A brake system for a vehicle, comprising:
a main brake cylinder;
a brake pedal configured to displace a piston in the main brake cylinder;
a brake booster; and
a device configured to vary a pedal resistance of the brake pedal, the device including:
at least one electroactive polymer actuator; and
a reaction disk, the reaction disk including at least two polymer actuators,
wherein the at least two polymer actuators are configured to be actuated independently of one another and are arranged coaxially to one another.

9. The brake system as claimed in claim 8, wherein:
the reaction disk is arranged between a brake piston and a booster piston in a first direction and the main brake cylinder in a second direction,
the brake piston is displaceable by the brake pedal,
the booster piston is displaceable by the brake booster, and
an inner polymer actuator of the at least two polymer actuators has a diameter that is smaller than or equal to a diameter of the brake piston.

10. The brake system as claimed in claim 8, wherein at least one of the at least two polymer actuators is a stack actuator.

11. A method for operating a device including at least one electroactive polymer actuator and a reaction disk, the reaction disk including at least two polymer actuators which are configured to be actuated independently of one another and are arranged coaxially to one another, the method comprising:
actuating the at least two polymer actuators independently of one another as a function of a desired pedal resistance.

12. The brake system as claimed in claim 8, wherein at least one of the at least two polymer actuators is a roller actuator.

13. The brake system as claimed in claim 10, wherein at least one of the at least two polymer actuators is a roller actuator.
